(19) United States
(12) Patent Application Publication
(10) Pub. No.: US 2015/0318656 A1
(43) Pub. Date: Nov. 5, 2015

(54) OPTICALLY PUMPED SOLID STATE LASER DEVICE WITH SELF ALIGNING PUMP OPTICS AND ENHANCED GAIN

(71) Applicant: STEPHAN GRONENBORN, AACHEN (DE)

(72) Inventor: STEPHAN GRONENBORN, AACHEN (DE)

(73) Assignee: KONINKLIJKE PHILIPS N.V., EINDHOVEN (NL)

(21) Appl. No.: 14/650,606

(22) PCT Filed: Nov. 5, 2013
(86) PCT No.: PCT/IB2013/059898

§ 371 Date: Jun. 9, 2015

Related U.S. Application Data
(60) Provisional application No. 61/735,682, filed on Dec. 11, 2012.

(51) Int. Cl. H01S 3/02; H01S 5/187; H01S 3/06; H01S 3/0941; H01S 5/42; H01S 5/34; H01S 3/042

(52) U.S. Cl. CPC H01S 3/025; H01S 5/34; H01S 5/187; H01S 3/042; H01S 3/09415; H01S 5/423; H01S 3/0604

(57) ABSTRACT

The present invention relates to an optically pumped solid state laser device, comprising one or several solid state laser media (100) in a laser resonator and one or several pump laser diodes (200) and pump radiation reflecting mirrors (300). The laser resonator is formed of one or several first resonator mirrors arranged at a first side of the solid state laser media (100) and one or several second resonator mirrors (310, 320, 330) arranged at a second side of the solid state laser media (100). The first and second resonator mirrors are arranged to guide laser radiation (500) on at least two different straight paths through each of said laser media (100). The pump laser diodes (200) are arranged to optically pump the solid state laser media (100) by reflection of pump radiation (510) at said pump radiation reflecting mirrors (300). The pump radiation reflecting mirrors (300) and the second resonator mirrors (310, 320, 330) are integrally formed in a single mirror element (600). With this design of the solid state laser device an easy alignment of the pump optics and an enhanced gain of the laser device are achieved. The proposed solid state laser device can be realized in a compact form.

### FIELD OF THE INVENTION

The present invention relates to an optically pumped solid state laser device comprising one or several solid state laser media in a laser resonator and one or several pump laser diodes to optically pump the solid state laser media, said laser resonator being formed of one or several first resonator mirrors arranged at a first side of said solid state laser media and one or several second resonator mirrors arranged at an opposing second side of said solid state laser media, said first and second resonator mirrors being arranged to guide laser radiation of said laser resonator on at least two different straight paths through each of said laser media. An example for optically pumped solid state laser devices of this kind are optically pumped vertical extended cavity surface emitting lasers (VECSELs) or semiconductor disc lasers (SDL) which offer a compact and low-cost solution for medium laser powers with high brightness, narrow bandwidth and short laser pulses. Such laser devices can be used for a huge number of applications requiring higher brightness and/or shorter pulses than can be delivered by laser diodes.

### BACKGROUND OF THE INVENTION AND PRIOR ART

Standard disc lasers need precise alignment of the pump lasers and the pump laser optics with respect to the optical mode of the laser resonator. This alignment is difficult during the fabrication of the laser device. Furthermore, such lasers are often limited in the power of the low brightness pump radiation that can be focused in a given active area of the laser medium which results in a low gain of the laser device. Also the maximum dissipated power density in the laser medium is often limited by the cooling method, in particular a heat sink onto which the laser medium is mounted.

U.S. Pat. No. 5,553,088 discloses a solid state laser device comprising one or several disc shaped solid state laser media in a laser resonator. The laser resonator in at least one of the embodiments is formed of a first resonator mirror formed of a first end face of the solid state laser medium and several second resonator mirrors arranged at an opposing second side of the solid state laser medium. The resonator mirrors are arranged to guide the laser radiation of the laser resonator on two different paths through the laser medium. The laser medium is pumped by several laser diodes from the side which are arranged at the same carrier element as the solid state laser medium. The proposed device allows an enhanced gain of the laser medium due to the propagation of the laser radiation on different paths through the laser medium. This also allows a better distribution of the generated heat and results in an improved cooling. The document does not propose any solution for an easier alignment of the pump optics in case of optical pumping through one of the end faces of the laser medium through which the laser radiation passes.

### SUMMARY OF THE INVENTION

It is an object of the present invention to provide an optically end-pumped solid state laser device with one or several solid state laser media which enables an easy alignment of the pump optics and can be realized in a compact manner.

The object is achieved with the optically end-pumped solid state laser device according to claim 1. Advantageous embodiments of the device are subject matter of the dependent claims or can be deduced from the subsequent portions of the description and preferred embodiments.

The proposed optically end-pumped solid state laser device comprises one or several preferably disc or plate shaped solid state laser media in a laser resonator. The laser resonator is formed of one or several first resonator mirrors arranged at a first side of the solid state laser media and one or several second resonator mirrors arranged at a second side of the solid state laser media opposing said first side. The first and second resonator mirrors are arranged to guide the laser radiation of the laser device on at least two different straight paths through each of said laser media. The laser can be designed for example to be a VECSEL wherein each laser medium is formed of a quantum-well structure on a DBR (distributed Bragg reflector) which forms one of the first resonator mirrors. Nevertheless, also other types of lasers may be realized, for example solid state lasers in which the solid state laser medium is a laser crystal. One or several laser pump laser diodes and pump radiation reflecting mirrors are arranged to optically pump the solid state laser media by reflection of the pump radiation of the pump laser diodes at said pump radiation reflecting mirrors. The pump radiation reflecting mirrors are situated on the second side together with the second resonator mirrors and are arranged and designed to directly reflect the pump radiation to the end faces of the solid state laser media on the second side. The pump reflecting mirrors and the second resonator mirrors are integrally formed in a single mirror element on the second side of the solid state laser media. The first resonator mirror or resonator mirrors may be formed of the end faces of the laser media on the first side. To this end, the end faces of crystalline laser media may be appropriately coated to achieve a high reflection of the laser radiation at these end faces. In case of VECSELs or semiconductor disc lasers the first resonator mirrors are formed of the DBR(s) on which the laser medium (active medium) is arranged. Nevertheless, it is also possible to provide the first resonator mirror(s) in form of separate mirror elements.

The solid state laser device of the present invention uses an appropriately designed mirror element which directs the pump light into the solid state laser media and at the same time forms the second resonator mirrors of the laser resonator. The pump radiation mirrors formed in this mirror element are designed to pump the areas of the laser media which cover the modes of the laser radiation on the different paths through these laser media. Therefore, the pump beams and the laser mode always overlap without complicated alignment since the parts of the mirror element forming the pump optics are always in a fixed spatial relationship to the parts of the mirror element forming the second resonator mirrors. With such a self-centering mirror element the alignment of the pump optics is significantly simplified. The proposed design allows the arrangement of the pump laser diodes close to the laser media resulting in a very compact design of the solid state laser device. Due to the different paths of the laser radiation through the solid state laser media, a higher amount of pump energy can be deposited resulting in an enhanced gain of the laser device compared with a similar laser in which the laser radiation always propagates on the same path through the laser medium. The different paths also allow a better heat distribution and thus a better cooling of the solid state laser device. The cooling is preferably achieved through cooling body with a plane surface onto which the laser media are mounted adjacent to each other. The pump laser diodes may also be mounted on this cooling body adjacent to and/or between the solid state laser media. The pump laser diodes then emit the pump radiation substantially perpendicular to the end faces of the solid state laser media towards the mirror element. The cooling body may be a heat sink of a bulk material, in particular a metal, and may also have cooling fins for air cooling. It is also possible to realize this cooling body as a chamber for a cooling liquid, for example water, which is pumped through the cooling body during operation of the laser device.

The pump laser diodes may be single diodes or arrays of laser diodes, for example vertical cavity surface emitting laser (VCSEL) arrays or microchip-VECSEL arrays. The body of the mirror element is preferably formed of an optically transparent material, for example a coated glass or coated plastics. The coating for the mirrors may be formed of a metallic coating or of a dielectric coating as known in the art.

The proposed laser device may comprise at least two solid state laser media mounted adjacent to each other on an appropriate carrier element, in particular a cooling body. Each of these laser media are preferably surrounded by several pump laser diodes on the carrier element. The mirror element may then comprise one pump radiation reflecting mirror for each of said laser media, said pump radiation reflecting mirror being preferably centered with respect to the corresponding laser media. On the mirror element, these pump radiation reflecting mirrors are arranged between the second resonator mirrors which reflect the laser radiation coming from one of the laser media to the adjacent laser medium. This results in a zig-zag-path of the laser radiation between the first and second resonator mirrors through the laser device and in the different straight paths through the laser media. The pump laser diodes and pump radiation reflecting mirrors are arranged and designed such that each of these paths is sufficiently optically pumped to achieve the required gain. One of the two outer resonator mirrors of the mirror element is designed to form the outcoupling mirror of the laser resonator. This means that this mirror allows the passage of a small portion of the laser radiation through the mirror to the outside of the laser resonator.

In a further embodiment, the proposed solid state laser device comprises one single solid state laser medium arranged on an appropriate carrier element. Also in this embodiment, the solid state laser medium is preferably surrounded by several pump laser diodes on said carrier element. In this embodiment the mirror element may comprise a central region which forms the second resonator mirrors and an outer region which is designed to reflect the pump radiation to the solid state laser medium and forms the pump radiation reflecting mirror(s). Depending on the number of second resonator mirrors, the laser radiation may be guided on substantially more than two different paths through the laser medium, resulting in a zig-zag-path of the laser radiation between the first and second resonator mirrors through the laser device like that in the previous embodiment. The outer region of the mirror element is then designed to generate an intensity distribution of the pump radiation at the facing end face of the solid state laser medium which covers the modes of all of the different paths of the laser radiation through this laser medium. Also in this embodiment one of the second resonator mirrors is designed to form the outcoupling mirror of the laser resonator.

These and other aspects of the invention will be apparent from and elucidated with reference to the embodiments described hereinafter.

### BRIEF DESCRIPTION OF THE DRAWINGS

The proposed solid state laser device is described in the following by way of examples in connection with the accompanying drawings in further detail. The figures show:

FIG. 1 a cross sectional side view of a first example of the proposed laser device;

FIG. 2 a top view on the solid state laser media of the laser device of FIG. 1;

FIG. 3 a top view on the mirror element of the laser device of FIG. 1;

FIG. 4 a cross sectional side view on a second example of the proposed solid state laser device;

FIG. 5 a top view on the solid state laser medium of the laser device of FIG. 4;

FIG. 6 a top view on the mirror element of the laser device of FIG. 4;

FIG. 7 a cross sectional view along ring path A indicated in FIG. 6.

### DETAILED DESCRIPTION OF EMBODIMENTS

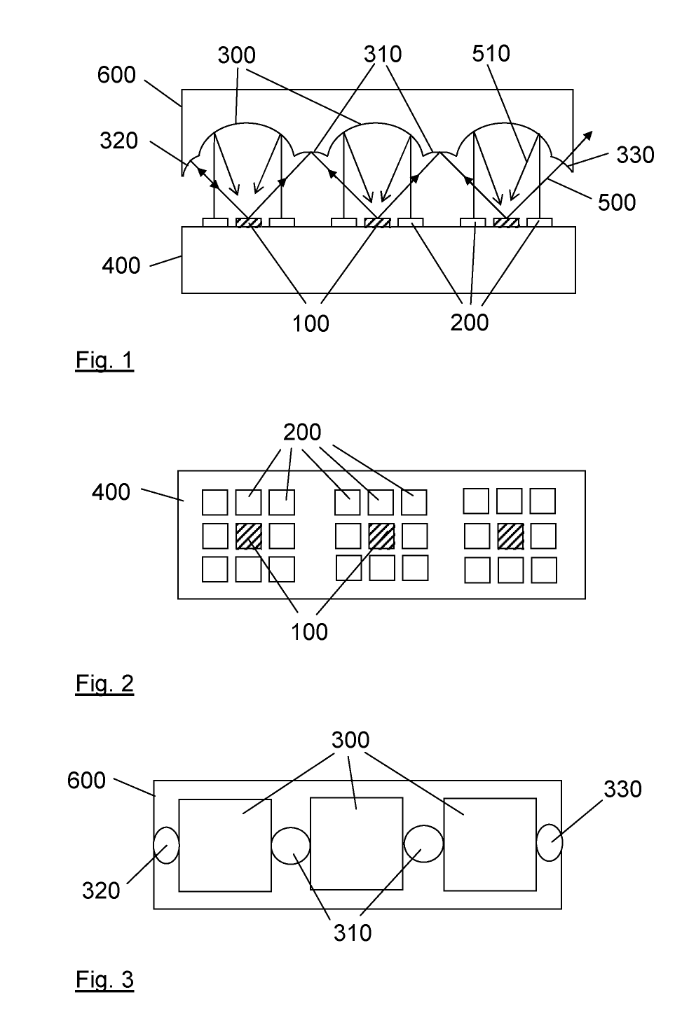

FIG. 1 shows a cross sectional side view of a first example of the proposed solid state laser device. The laser device comprises three plate shaped solid state laser media 100 mounted side by side on a plane surface of a heat sink 400. Each of these laser media 100 may be formed of the active area of a VCSEL and is surrounded by several pump laser diodes 200 as can be recognized from the top view onto the laser media and heat sink shown in FIG. 2. The laser resonator in this example is formed of seven resonator mirrors arranged on both sides of the laser media. The first resonator mirrors are formed of the DBRs of the VCSELs which provide the laser media 100. The end mirror 320, the outcoupling mirror 330 and two folding mirrors 310 are arranged on the opposing second side of the laser media 100. With the shown arrangement of the resonator mirrors the laser radiation 500 propagates on a zig-zag-path through the laser device. Each of the laser media 100 is passed on two different paths. The arrangement also comprises three pump radiation reflecting mirrors 300 which are arranged and designed to direct the pump radiation 510 towards the end faces of the laser media 100. The second resonator mirrors 310, 320, 330 are integrally formed together with the pump radiation reflecting mirrors 300 in one single optical element 600. Since this optical element can be fabricated with high precision, the relative orientation and arrangement between the pump radiation reflecting mirrors 300, i.e. the pump optics, and the second resonator mirrors 310, 320, 330 can be ensured perfectly without any further alignment. Thus the alignment of the pump optics with respect to the laser resonator is achieved very easily when mounting the proposed laser device. The pump radiation reflecting mirrors are formed of three parabolic surfaces as indicated in FIG. 1. The radiation of the pump laser diodes 200 is thus reflected and focused on the active media (laser media 100) and overlaps with the optical mode of the resonator in these media.

FIG. 3 shows a top view on the optical element 600 in which the adjacent arrangement of the pump radiation reflecting mirrors 300 and the second laser mirrors, end mirror 320, folding mirrors 310 and outcoupling mirror 330, can be recognized.

Of course, the three laser media 100 could also be replaced by a single, rectangular shaped active medium extending between the two outer laser media 100 of FIG. 1. The pump laser diodes 200 would then be located along the long edges of the rectangular laser medium. The mirror element 600 would provide the folding mirrors 310 directly adjacent to each other with the pump mirrors 300 on both sides. Of course, this is only one of several further possibility of an arrangement according to the present invention.

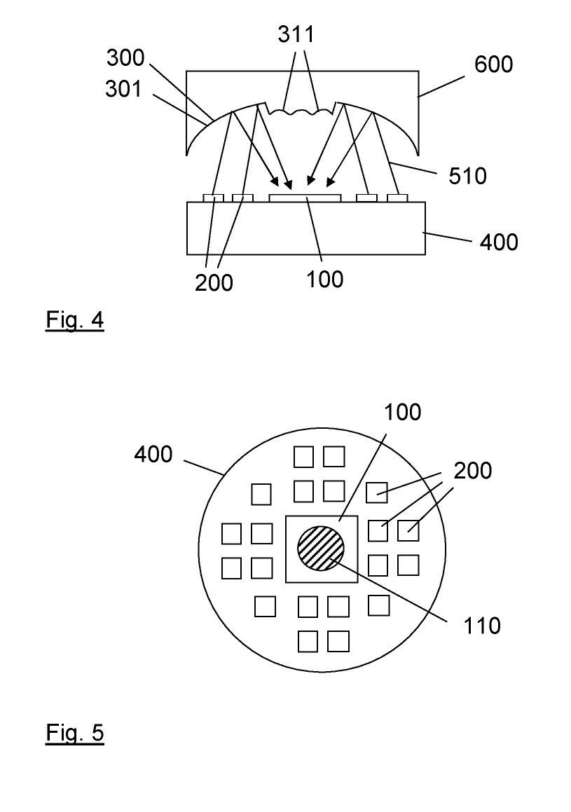

FIG. 4 shows a side view of a second example of the proposed solid state laser device. In this example only one solid state laser medium 100 is arranged on a plane surface of a heat sink 400. This solid state laser medium is surrounded by several pump laser diodes on the same surface of the heat sink 400. An example for such an arrangement of the pump laser diodes 200 is shown in the top view on the solid state laser medium 100 in FIG. 5.

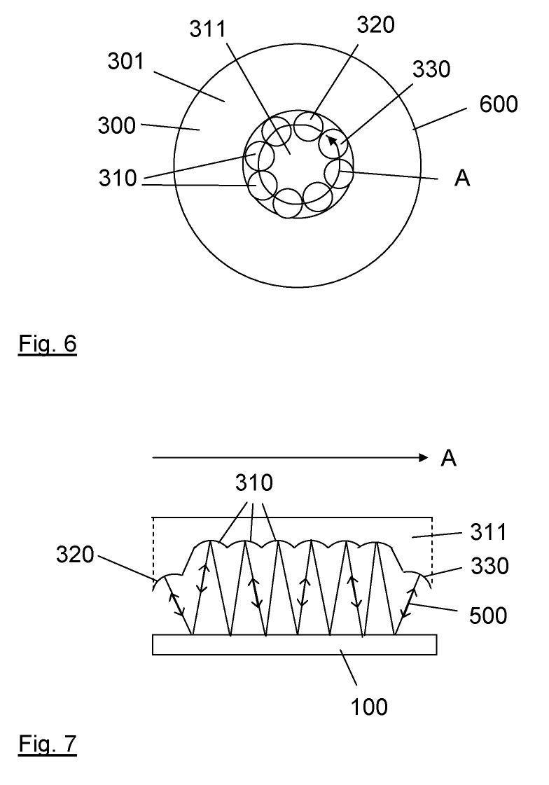

The mirror element 600 in this embodiment comprises an outer section 301 reflecting the pump radiation onto the end face of the solid state laser medium 100. The central portion 311 of the mirror element 600 forms the second resonator mirrors. In this case, the radiation of all pump laser diodes 200 is focused by the pump radiation reflecting mirror(s) in outer portion 301 of the mirror element 600 on a single spot 110 which is larger than the typical mode size of the resonator (see FIG. 5). For state of the art disc lasers, a pumped area much larger than the mode size would result in multimode operation with a reduced brightness. In this embodiment however a circular arrangement of several folding mirrors 310 reflects the laser mode at several different positions through the pumped area 110. This arrangement of the folding mirrors 310 is shown in the top view on the reflecting side of the mirror element 600 shown in FIG. 6.

FIG. 7 shows the optical paths of the laser radiation in a cross sectional view along circular line A indicated in FIG. 6. In this cross sectional view also the end mirror 320 and the outcoupling mirror 330 of the laser resonator are indicated. Since FIG. 7 shows a cross section along a circular line, the resonator end mirror 320 and the outcoupling mirror 330 are arranged adjacent to each other on the mirror element 600. It is obvious for the skilled person that also the central part of the pumped area can be filled with the optical mode by an appropriate arrangement of the folding mirrors 310.

While the invention has been illustrated and described in detail in the drawings and forgoing description, such illustration and description are to be considered illustrative or exemplary and not restrictive; the invention is not limited to the disclosed embodiments. For example, although the figures show only three different laser media, another number of such media can be provided, for example two or more than three. The number of different paths through the laser media or through the whole device, in particular forming the zig-zag-path, and the corresponding folding mirrors 310 are not limited to the disclosed number. Furthermore, functional laser elements for the solid state laser like etalons, non-linear crystals, SESAMs (Semiconductor Saturable Absorber Mirrors), saturable absorbers, polarizers, Pockels-cells, AOMs (Acousto-Optical Modulators) . . . can be integrated in the laser device. Other variations of the disclosed embodiments can be understood and effected by those skilled in the art in practicing the claimed invention, from a study of the drawings, the disclosure, and the appended claims. In the claims the word “comprising” does not exclude other elements or steps and the indefinite article “a” or “an” does not exclude a plurality. The mere fact that certain measures are recited in mutually different dependent claims does not indicate that a combination of these measures can not be used to advantage. In particular, all claims of the device can be freely combined if this makes sense. The reference signs in the claims should not be construed as limiting the scope.

### LIST OF REFERENCE SIGNS

100 laser medium
110 pumped area
200 pump laser diode
300 pump radiation reflecting mirror
301 outer portion of mirror element
310 resonator folding mirror
311 central portion of mirror element
320 resonator end mirror
330 resonator outcoupling mirror
400 heat sink
500 laser radiation
510 pump radiation
600 mirror element

1. An optically pumped solid state laser device, comprising:
at least one solid state laser media in a laser resonator,
said laser resonator being formed of at least one first resonator mirrors arranged at a first side of the at least one solid state laser media and at least one second resonator mirrors arranged at a second side of the at least one solid state laser media opposing said first side,
said at least one first and second resonator mirrors being arranged to guide laser radiation of said laser resonator on at least two different straight paths through each of said laser media,
at least one pump laser diodes and pump radiation reflecting mirrors,
said at least one pump laser diodes being arranged to optically pump said at least one solid state laser media by reflection of pump radiation at said pump radiation reflecting mirrors,
said pump radiation reflecting mirrors being arranged on said second side and designed to directly reflect said pump radiation to the at least one solid state laser media,
wherein said pump reflecting mirrors and said at least one second resonator mirrors, are integrally formed in a single mirror element.

2. The device according to claim 1, wherein said at least one solid state laser media are mounted side by side on a cooling body.

3. The device according to claim 1, wherein said at least one solid state laser media are formed of quantum-well structures on distributed Bragg reflectors.

4. The device according to claim 2, further comprising at least two of said solid state laser media, each surrounded by several of said pump laser diodes on said cooling body.

5. The device according to claim 4, wherein the mirror element comprises one pump radiation reflecting mirror for each of said laser media, said pump radiation reflecting mirror being arranged between said second resonator mirrors and an outer one of said second resonator mirrors being designed to form an outcoupling mirror.

6. The device according to claim 2, further comprising one single of said solid state laser media surrounded by several of said pump laser diodes on said cooling body.

7. The device according to claim 6, wherein the mirror element comprises a central region which forms said second resonator mirrors and an outer region which is designed to reflect said pump radiation to the solid state laser medium and forms said pump radiation reflecting mirror, one of said second resonator mirrors being designed to form an outcoupling mirror.

8. The device according to claim 7, wherein said outer region of said mirror element is designed to generate an intensity distribution of the pump radiation in said solid state laser medium, the intensity distribution covering all of said different paths of the laser radiation through the solid state laser medium.

9. The device according to claim 2, wherein said pump laser diodes are arranged on said cooling body to surround each of said solid state laser media.

10. The device according to claim 2, wherein said pump laser diodes are vertical cavity surface emitting lasers or electrically pumped vertical extended cavity surface emitting lasers.
